(19) United States
(12) Patent Application Publication
(10) Pub. No.: US 2026/0215202 A1
(43) Pub. Date: Jul. 23, 2026

(54) SUBSTRATE ETCHING APPARATUS AND SUBSTRATE ETCHING METHOD

(71) Applicant: Samsung Display Co., LTD., Yongin-si (KR)

(72) Inventors: SEUNGBAE KANG, Yongin-si (KR); YOUNGROK KIM, Yongin-si (KR); WOOJIN CHO, Yongin-si (KR)

(21) Appl. No.: 19/447,555

(22) Filed: Jan. 13, 2026

(30) Foreign Application Priority Data
Jan. 17, 2025 (KR) 10-2025-0007453

(51) Int. Cl. H10P 72/00

(52) U.S. Cl. CPC H10P 72/0424; H10P 72/0606

(57) ABSTRACT

Provided are a substrate etching apparatus and a substrate etching method. The substrate etching apparatus may include a rotation drive unit including a turntable on which a substrate is arranged and a rotation module that rotates the turntable, a first nozzle unit which sprays an etching solution onto the substrate, a second nozzle unit positioned at a different position with respect to the substrate compared to the first nozzle unit and which sprays an etching solution onto the substrate based on a height difference in the etching solution which has been sprayed onto the substrate, and a controller which controls a spray amount of the etching solution by at least one of the first nozzle unit and the second nozzle unit.

This application claims priority to Korean Patent Application No. 10-2025-0007453, filed on Jan. 17, 2025, and all the benefits accruing therefrom under 35 U.S.C. § 119, the content of which in its entirety is herein incorporated by reference.

### BACKGROUND

### 1. Field

The present disclosure relates to a substrate etching apparatus and a substrate etching method.

### 2. Description of the Related Art

As demand for display devices expands, the desire for display devices that may be used for various purposes is also increasing. In line with this trend, display devices are gradually becoming larger or thinner, and the desire for substrate etching apparatuses and substrate etching methods is also increasing, in order to develop display devices that are larger and thinner and have accurate and clear colors.

### SUMMARY

Embodiments of the present disclosure provide a substrate etching apparatus and a substrate etching method for manufacturing a display substrate with improved optical properties.

However, these objectives are examples and the objectives to be solved by the present disclosure are not limited thereto.

An aspect of the present disclosure may include a substrate etching apparatus including: a rotation drive unit including a turntable on which a substrate is arranged and a rotation module that rotates the turntable, a first nozzle unit which sprays an etching solution onto the substrate, a second nozzle unit positioned at a different position with respect to the substrate compared to the first nozzle unit and which sprays an etching solution onto the substrate based on a height difference in the etching solution which has been sprayed onto the substrate, and a controller which controls a spray amount of the etching solution by at least one of the first nozzle unit and the second nozzle unit.

In some embodiments, the first nozzle unit and the second nozzle unit may be each independently driven.

In some embodiments, the etching solution sprayed by the first nozzle unit is radially discharged by centrifugal force.

In some embodiments, the first nozzle unit and the second nozzle unit may spray the etching solution in a spray manner while etching is performed on the substrate.

In some embodiments, the first nozzle unit may be positioned closer to a center portion of the substrate than the second nozzle unit.

In some embodiments, the first nozzle unit may spray a greater amount of the etching solution compared to the second nozzle unit.

In some embodiments, the second nozzle unit may spray the etching solution while moving in a direction away from a center portion of the substrate.

In some embodiments, the second nozzle unit may spray a smaller amount of the etching solution the farther away from the center portion of the substrate.

In some embodiments, the second nozzle unit may spray the etching solution at a lower spray pressure the farther away from the center portion of the substrate.

In some embodiments, the substrate etching apparatus may further include a height measuring unit measuring a height of the etching solution which has been sprayed onto and is distributed on the substrate.

In some embodiments, the height measuring unit may measure the height of the etching solution at multiple positions in a direction away from a center portion of the substrate.

Another aspect of the present disclosure may include preparing a substrate, while rotating the substrate, spraying, by a first nozzle portion, an etching solution onto the substrate, and spraying, by a second nozzle portion, the etching solution onto the substrate based on a height difference in the etching solution which has been sprayed onto the substrate.

In some embodiments, the first nozzle portion and the second nozzle portion may be each independently driven to spray the etching solution onto the substrate.

In some embodiments, the etching solution sprayed by the first nozzle unit is radially discharged by centrifugal force.

In some embodiments, the first nozzle portion may spray a greater amount of the etching solution compared to the second nozzle portion.

In some embodiments, the second nozzle portion may spray the etching solution while moving in a direction away from a center portion of the substrate.

In some embodiments, the second nozzle portion may spray a smaller amount of the etching solution the farther away from the center portion of the substrate.

In some embodiments, the spraying, by the second nozzle portion, of the etching solution onto the substrate may include measuring, at multiple positions, a height of the etching solution which has been sprayed onto the substrate, and calculating, based on a difference between the measured heights of the etching solution, an amount of etching solution to be additionally sprayed.

In some embodiments, the spraying, by the second nozzle portion, of the etching solution onto the substrate may further include spraying, by the second nozzle portion, the etching solution onto the substrate based on the calculated amount.

In some embodiments, the measuring, at the multiple positions, the height of the etching solution which has been sprayed on the substrate may include measuring the height of the etching solution at the multiple positions in a direction away from a center portion of the substrate.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a perspective view schematically illustrating a display device according to an embodiment of the present disclosure;

FIG. 2 is a cross-sectional view schematically illustrating an example of cross-section I-I′ of FIG. 1;

FIG. 3 is a cross-sectional diagram schematically illustrating a structure of a pixel;

FIG. 4 is a perspective view schematically illustrating a portion of a configuration of a substrate etching apparatus according to an embodiment of the present disclosure;

FIG. 5 is a structural block diagram of a substrate etching apparatus according to an embodiment of the present disclosure;

FIG. 6 is a plan view schematically illustrating the substrate etching apparatus of FIG. 4;

FIG. 7 is a front view schematically illustrating the substrate etching apparatus of FIG. 4;

FIG. 8 is a diagram for describing driving of a first nozzle unit and a second nozzle unit of FIG. 4;

FIG. 9 is a diagram for describing a driving method of the substrate etching apparatus of FIG. 4

FIG. 10A is a diagram schematically illustrating a substrate being etched by a substrate etching apparatus according to the related art;

FIG. 10B is a diagram schematically illustrating a substrate being etched by a substrate etching apparatus according to the present disclosure;

FIG. 11 is a flowchart for describing a substrate etching method according to an embodiment of the present disclosure;

FIG. 12 is a flowchart for describing an operation of a second nozzle portion of FIG. 8, which sprays an etching solution onto a substrate;

FIG. 13 is a block diagram of an electronic device according to an embodiment of the present disclosure; and

FIG. 14 is a schematic diagram of an electronic device according to various embodiments.

### DETAILED DESCRIPTION

As the present disclosure allows for various changes and numerous embodiments, particular embodiments will be illustrated in the drawings and described in detail in the written description. The effects and features of the present disclosure, and ways to achieve them will become apparent by referring to embodiments that will be described later in detail with reference to the drawings. However, the present disclosure is not limited to the following embodiments but may be embodied in various forms.

It will be understood that although the terms “first,” “second,” and the like may be used herein to describe various elements, these elements should not be limited by these terms. These terms are used to distinguish one element from another.

Singular expressions, unless defined otherwise in contexts, include plural expressions.

In the embodiments below, it will be further understood that the terms “comprise” and/or “have” used herein specify the presence of stated features or elements, but do not preclude the presence or addition of one or more other features or elements.

In the embodiments below, when a part such as a unit, region, or element is described as being located above or on another part, this includes not only the case where the part is directly above the other part, but also the case where another unit, region, element, or part is therebetween.

In the embodiments below, terms such as “connect” or “combine” do not necessarily imply a direct and/or fixed connection or combination of two members, unless the context clearly indicates otherwise, and do not exclude the presence of another member between the two members.

In some aspects, in the drawings, for convenience of description, sizes of elements may be exaggerated or contracted. For example, the size and/or thickness of each element illustrated in the drawings are arbitrarily illustrated for convenience of description, and therefore the present disclosure is not necessarily limited to the drawings.

Hereinafter, embodiments of the present disclosure will be described in detail with reference to the attached drawings. In an example in which describing with reference to the drawings, identical or corresponding elements are given the same drawing reference numerals and redundant descriptions thereof will be omitted.

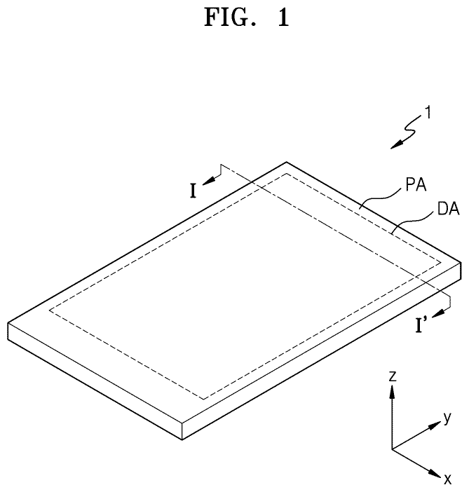

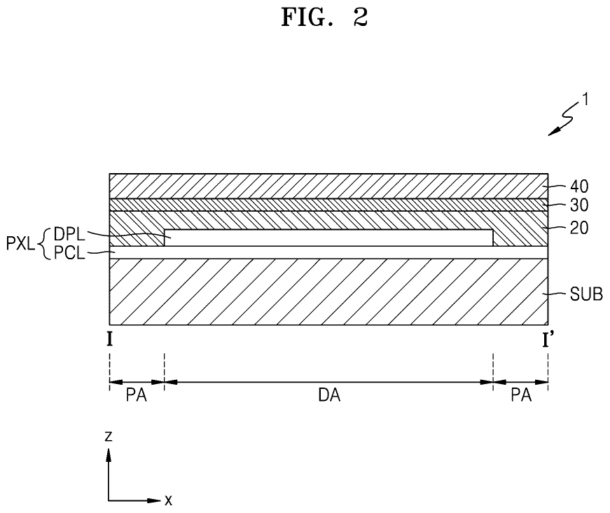

FIG. 1 is a perspective view schematically illustrating a display device according to an embodiment of the present disclosure, and FIG. 2 is a cross-sectional view schematically illustrating an example of a cross-section I-I′ of FIG. 1.

Referring to FIG. 1, a display device 1 according to an embodiment of the present disclosure may include a display area DA and a peripheral area PA. The peripheral area PA may be arranged to surround the display area DA on the periphery of the display area DA. The peripheral area PA may have various wiring and driving circuits configured to transmit electrical signals to be applied to the display area DA. The display device 1 may provide a certain image by using light emitted from a plurality of pixels arranged in the display area DA. Although not illustrated, the display device 1 may be bendable by including a bending region in some areas of the peripheral area PA.

The display device 1 may include a display device such as, for example, an organic light-emitting display device 1, an inorganic light-emitting display device (or inorganic electroluminescent (EL) display device), or a quantum dot light-emitting display device. Herein, the organic light-emitting display device 1 will be described as an example. The display device 1 may be implemented as various types of electronic devices such as, for example, a mobile phone, a laptop computer, and a smart watch.

As illustrated in FIG. 2, the display device 1 may include a substrate SUB sequentially stacked in a thickness direction (z-direction), a pixel layer PXL on the substrate SUB, an encapsulation member 20 sealing the pixel layer PXL, a touch sensing layer 30 on the encapsulation member 20, and a cover layer 40 on the touch sensing layer 30.

The substrate SUB may include a glass material or a polymer resin. For example, the substrate SUB may include a glass material mainly including SiO₂, or may include various materials having flexible or bendable properties, for example, a resin such as, for example, a reinforced plastic. Although not illustrated, the substrate SUB may be bendable by including a bendable region in some areas of the peripheral area PA.

The pixel layer PXL may be arranged on the substrate SUB. The pixel layer PXL may include a display element layer DPL including display elements arranged in each pixel and a pixel circuit layer PCL including a pixel circuit arranged in each pixel and insulating layers. The display element layer DPL may be arranged on the pixel circuit layer PCL and include a plurality of insulating layers arranged between the pixel circuits and the display elements. Some of wiring and insulating layers of the pixel circuit layer PCL may extend to the peripheral area PA.

The encapsulation member 20 may include a thin-film encapsulation layer. The thin-film encapsulation layer may include at least one inorganic encapsulation layer and at least one organic encapsulation layer. In an example in which the display device 1 has the substrate SUB including a polymer resin, and the encapsulation member 20 of a thin-film encapsulation layer including an inorganic encapsulation layer and an organic encapsulation layer, flexibility of the display device 1 may be improved.

The touch sensing layer 30 may obtain coordinate information according to an external input, such as, for example, a touch event.

The touch sensing layer 30 may include sensing electrodes (or touch electrodes) and signal lines (trace lines) connected to the sensing electrodes. The touch sensing layer 30 may detect an external input by using a mutual cap method or/and a self cap method.

As an embodiment, the touch sensing layer 30 may be of a capacitive type, and when the cover layer 40 is touched, a change in capacitance occurs between the sensing electrode of the touch sensing layer 30 and an opposite electrode, and by detecting the change, whether the corresponding portion is in contact may be determined.

The touch sensing layer 30 may be formed directly on a display panel, or may be formed separately and then bonded through an adhesive layer such as, for example, an optical clear adhesive (OCA). For example, the touch sensing layer 30 may be formed continuously after a process of forming the display panel, in which case an adhesive layer may not be between the touch sensing layer 30 and the display panel.

The cover layer 40 may be arranged on the touch sensing layer 30 to protect the display device 1.

The cover layer 40 may have flexible characteristics. The cover layer 40 may include polymethyl methacrylate, polydimethylsiloxane, polyimide, acrylate, polyethylene terephthalate, polyethylene naphthalate, or the like. However, embodiments of the present disclosure are not limited thereto, and the cover layer 40 may include various materials such as, for example, metal, and in some cases, a thin metal foil such as, for example, steel use stainless (SUS) may be used.

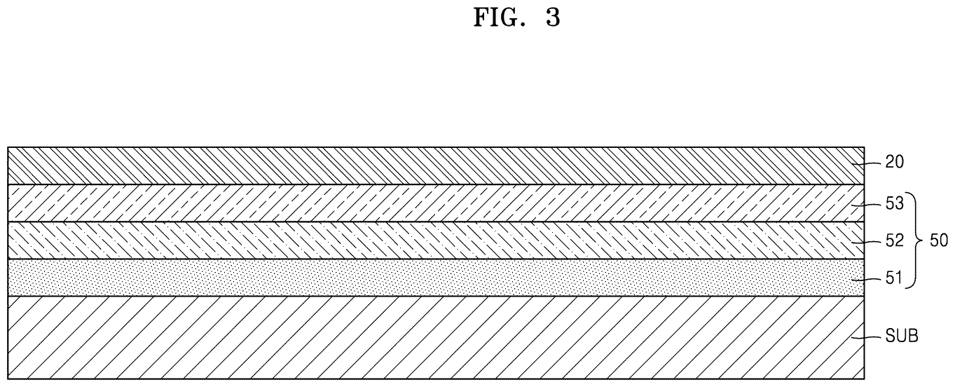

FIG. 3 is a cross-sectional diagram schematically illustrating a structure of a pixel.

Referring to FIG. 3, a pixel may include a pixel circuit and an organic light-emitting diode 50 electrically connected to the pixel circuit.

Each pixel may be configured to emit light of, for example, red, green, blue or white color via the organic light-emitting diode 50.

The organic light-emitting diode 50 may include a pixel electrode 51, an intermediate layer 52, and an opposite electrode 53.

The pixel electrode 51 may be arranged on the substrate SUB. Here, the pixel electrode 51 is not necessarily arranged directly on an upper surface of the substrate SUB, but at least one insulating layer or electrode layer may be further arranged between the pixel electrode 51 and the substrate SUB.

The pixel electrode 51 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 51 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof.

The intermediate layer 52 includes an emission layer. The emission layer may include a polymer or low-molecular organic material, which emits light of a certain color. In an embodiment, the intermediate layer 52 may include a first functional layer disposed below the emission layer and/or a second functional layer disposed above the emission layer. The first functional layer and/or the second functional layer may include a layer that is a single body across the plurality of pixel electrodes 51, or may include a layer patterned to correspond to each of the plurality of pixel electrodes 51.

The first functional layer may include a single-layer or multi-layer. In an example in which the first functional layer includes a polymer material, the first functional layer may be a single-layer hole transport layer (HTL) and may include poly(3,4-ethylenedioxythiophene) (PEDOT) or polyaniline (PANI). In an example in which the first functional layer includes a low-molecular-weight material, the first functional layer may include a hole injection layer (HIL) and a hole transport layer (HTL).

The second functional layer is not always included. In an example in which the first functional layer and the emission layer include a polymer material, the second functional layer may be formed to improve the characteristics of the organic light-emitting diode 50. The second functional layer may be a single-layer or multi-layer. The second functional layer may include an electron transport layer (ETL) and/or an electron injection layer (EIL).

The opposite electrode 53 is arranged to face the pixel electrode 51, with the intermediate layer 52 between the opposite electrode 53 and the pixel electrode 51. The opposite electrode 53 may include a conductive material with a low work function. For example, the opposite electrode 53 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 53 may further include a layer such as, for example, ITO, IZO, ZnO or In₂O₃ on the (semi)transparent layer including the material described herein.

The opposite electrode 53 may be arranged on the intermediate layer 52. The opposite electrode 53 may be formed as a single body with a plurality of organic light-emitting diodes 50 in the display area DA and face the plurality of pixel electrodes 51.

A thin-film encapsulation layer may be arranged, as the encapsulation member 20, on the opposite electrode 53. The thin-film encapsulation layer protects the organic light-emitting diode 50 from moisture or oxygen from the outside. The thin-film encapsulation layer may have a multilayer structure. For example, the thin-film encapsulation layer may include a plurality of inorganic layers and a plurality of organic layers. By forming the thin-film encapsulation layer in a multilayer structure, even if a crack occurs within the thin-film encapsulation layer, the crack may be prevented from connecting between each inorganic layer and each organic layer. Accordingly, formation of a path through which moisture or oxygen from the outside penetrates into the display area may be prevented or minimized. In other embodiments, the number of organic layers, the number of inorganic layers, and the stacking order may be varied.

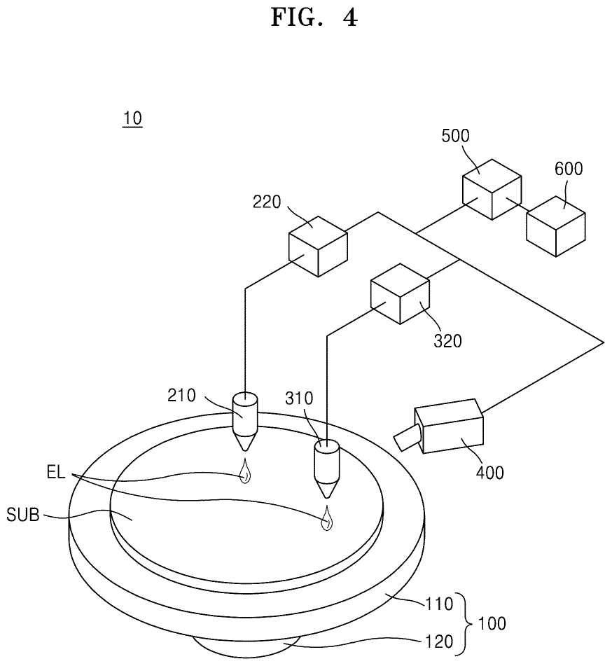

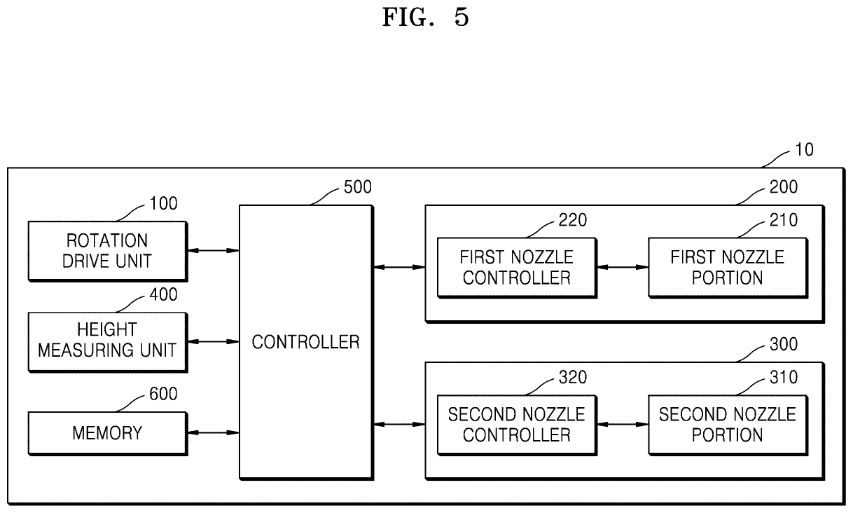

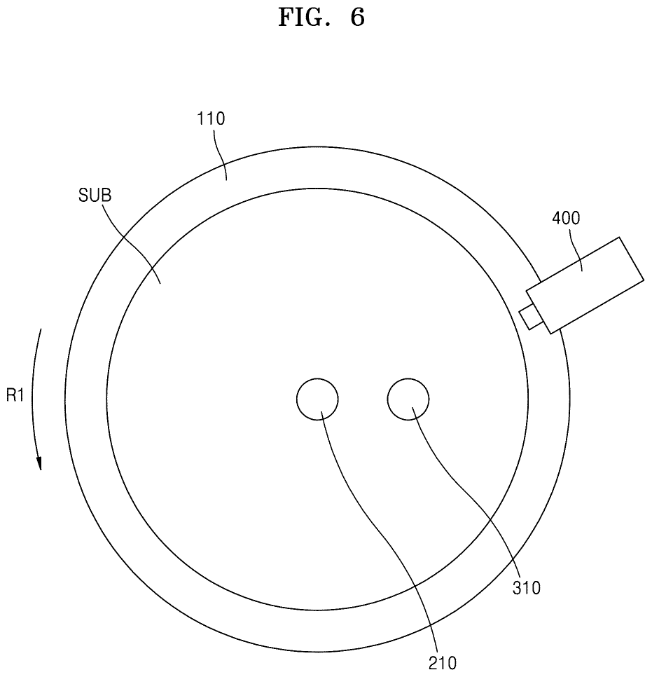

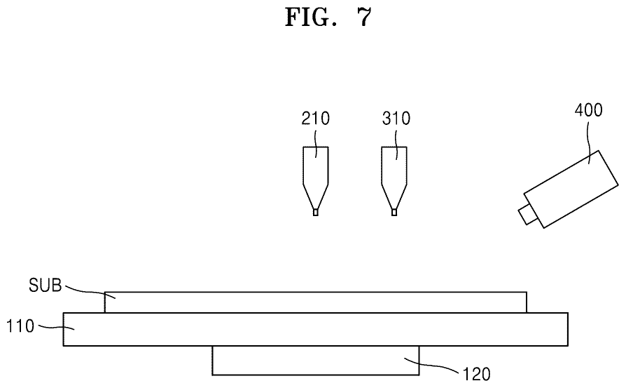

FIG. 4 is a perspective view schematically illustrating a portion of a configuration of a substrate etching apparatus according to an embodiment of the present disclosure, and FIG. 5 is a structural block diagram of a substrate etching apparatus according to an embodiment of the present disclosure. FIG. 6 is a plan view schematically illustrating the substrate etching apparatus of FIG. 4, and FIG. 7 is a front view schematically illustrating the substrate etching apparatus of FIG. 4.

Referring to FIGS. 4 to 7, a substrate etching apparatus 10 according to an embodiment of the present disclosure may include a rotation drive unit 100, a first nozzle unit 200, a second nozzle unit 300, and a controller 500.

The substrate etching apparatus 10 according to the present embodiment may be used to etch the substrate SUB.

The substrate SUB may refer to at least one layer that is formed on the substrate SUB described with reference to FIGS. 1 to 3.

For example, a material for forming a pattern of the pixel electrode 51 may be stacked on the substrate SUB. As an example, a metal layer for forming the pixel electrode 51 may be formed on the substrate SUB. For example, a layer containing silver (Ag) may be formed on the substrate SUB to form the pixel electrode 51.

The substrate etching apparatus 10 according to the present embodiment may be used to etch a layer formed on the substrate SUB. That is, the substrate etching apparatus 10 may be used to form a certain pattern by etching a metal layer formed on the substrate SUB. For example, the substrate etching apparatus 10 may be used to form a pattern of the pixel electrode 51 by etching a metal layer formed on the substrate SUB. However, embodiments of the present disclosure are not limited thereto, and the substrate etching apparatus 10 may be used to form a pattern of a metal layer other than the pixel electrode 51.

Accordingly, the substrate SUB included in the wordings such as, for example, ‘on the substrate SUB’, ‘the substrate SUB is’, and the like herein may be interpreted to mean that at least one layer, particularly, a metal layer, is formed on the substrate SUB.

The rotation drive unit 100 is a component on which the substrate SUB is arranged. That is, the substrate SUB may be arranged on the rotation drive unit 100 for etching.

The rotation drive unit 100 may include a turntable 110 and a rotation module 120.

The turntable 110 is a component on which the substrate SUB is arranged, and may be formed in a shape of a plate to support the substrate SUB. For example, the area of the turntable 110 may be larger than the area of substrate SUB.

The turntable 110 may be configured to be rotatable. That is, after the substrate SUB is mounted on the turntable 110, the turntable 110 may rotate. Accordingly, as the turntable 110 rotates, the substrate SUB may rotate together with the turntable 110, and an etching process may be performed on the substrate SUB that is rotating.

The rotation module 120 may rotate the turntable 110. That is, the rotation module 120 is a component that is connected to the turntable 110 and rotates the turntable 110 in at least one direction.

For example, the rotation module 120 may include a motor or the like that generates driving force to rotate the turntable 110.

The first nozzle unit 200 may spray an etching solution EL onto the substrate SUB.

As an embodiment, the first nozzle unit 200 may include a first nozzle portion 210 and a first nozzle controller 220.

The first nozzle portion 210 may refer to a component that directly sprays the etching solution EL onto the substrate SUB.

The first nozzle controller 220 may refer to a component that controls each component of the first nozzle unit 200 such that the first nozzle portion 210 sprays the etching solution EL onto the substrate SUB. For example, the first nozzle controller 220 may move the first nozzle portion 210 to a certain position, control the amount of etching solution EL sprayed by the first nozzle portion 210, or control a spraying pressure at which the first nozzle portion 210 sprays the etching solution EL.

As an embodiment, although not illustrated in the drawing, the first nozzle unit 200 may further include an etching solution supply unit. The etching solution supply unit may be a tank that stores the etching solution EL. The etching solution supply unit may supply the stored etching solution EL to the first nozzle portion 210 through a pipe.

The second nozzle unit 300 may spray the etching solution EL onto the substrate SUB.

As an embodiment, the second nozzle unit 300 may include a second nozzle portion 310 and a second nozzle controller 320.

The second nozzle portion 310 may refer to a component that directly sprays the etching solution EL onto the substrate SUB.

The second nozzle controller 320 may refer to a component that controls each component of the second nozzle unit 300 such that the second nozzle portion 310 sprays the etching solution EL onto the substrate SUB. For example, the second nozzle controller 320 may move the second nozzle portion 310 to a certain position, control the amount of etching solution EL sprayed by the second nozzle portion 310, or control the spraying pressure at which the second nozzle portion 310 sprays the etching solution EL.

As an embodiment, although not illustrated in the drawing, the second nozzle unit 300 may further include an etching solution supply unit. The etching solution supply unit may be a tank that stores the etching solution EL. The etching solution supply unit may supply the stored etching solution EL to the second nozzle portion 310 through the pipe.

As an embodiment, the second nozzle unit 300 may be positioned at a different position with respect to the substrate SUB compared to the first nozzle unit 200. For example, the first nozzle portion 210 and the second nozzle portion 310 may be positioned at different positions with respect to the substrate SUB. Accordingly, the first nozzle portion 210 and the second nozzle portion 310 may spray the etching solution EL to different positions on the substrate SUB.

The second nozzle unit 300 may spray the etching solution EL onto the substrate SUB based on a height difference in the etching solution EL which has been sprayed onto the substrate SUB (i.e., a height difference in the etching solution EL which is present on the substrate SUB).

In detail, the second nozzle unit 300 may spray a relatively large amount of the etching solution EL at a location where a height of the etching solution EL is relatively low and spray a relatively small amount of the etching solution EL at a location where the height of the etching solution EL is relatively high, thereby controlling a dip level of the etching solution EL distributed on the substrate SUB.

Driving of the first nozzle unit 200 and the second nozzle unit 300 is described in detail later.

As an embodiment, the substrate etching apparatus 10 may further include a height measuring unit 400.

The height measuring unit 400 may measure a height of the etching solution EL which has been sprayed onto and is distributed on the substrate SUB. For example, the height measuring unit 400 may measure the height of the etching solution EL sprayed on the substrate SUB, at multiple positions on the substrate SUB. For example, the height measuring unit 400 may include a camera or an imaging device, and may measure the height based on image data captured from the substrate.

The height of the etching solution EL measured by the height measuring unit 400 may be used as basic information for the second nozzle unit 300 to spray the etching solution EL. That is, the second nozzle unit 300 may control the dip level of the etching solution EL by spraying the etching solution EL based on the height of the etching solution EL, which is measured by the height measuring unit 400.

Driving of the height measuring unit 400 is described in detail later.

As an embodiment, the substrate etching apparatus 10 may further include the controller 500.

The controller 500 may be connected to each component of the substrate etching apparatus 10 and control the overall operation of the substrate etching apparatus 10. For example, the controller 500 may include a plurality of components, or may be provided as a single component.

As an embodiment, the controller 500 may control rotation of a rotation drive module. In an example in which the substrate SUB is arranged on the rotation drive module, the controller 500 may control the rotation drive module to rotate the turntable 110. Accordingly, an etching process may be performed while the turntable 110 on which the substrate SUB is mounted rotates.

As an embodiment, the controller 500 may control spraying, by the first nozzle unit 200, of the etching solution EL. For example, the controller 500 may change a position of the first nozzle portion 210 such that the first nozzle unit 200 sprays the etching solution EL at a certain position. In some embodiments, the controller 500 may control the amount of etching solution EL sprayed such that the first nozzle portion 210 sprays a certain amount of the etching solution EL. In some embodiments, the controller 500 may control the first nozzle unit 200 such that the first nozzle portion 210 sprays the etching solution EL at a certain pressure.

As an embodiment, the controller 500 may control spraying, by the second nozzle unit 300, of the etching solution EL. For example, the controller 500 may change a position of the second nozzle portion 310 such that the second nozzle unit 300 sprays the etching solution EL at a certain position. In some embodiments, the controller 500 may control the amount of the etching solution EL sprayed such that the second nozzle portion 310 sprays a certain amount of the etching solution EL. In some embodiments, the controller 500 may control the second nozzle unit 300 such that the second nozzle portion 310 sprays the etching solution EL at a certain pressure.

As an embodiment, the controller 500 may control measuring, by the height measuring unit 400, of the height of the etching solution EL. For example, the controller 500 may change a position of the height measuring unit 400 or control a measuring operation of the height measuring unit 400. In some embodiments, the controller 500 may calculate a spray amount of the etching solution EL to be sprayed by the second nozzle unit 300, based on the height of the etching solution EL, measured by the height measuring unit 400, and control the second nozzle unit 300 based on the calculated spray amount.

As an embodiment, the substrate etching apparatus 10 may further include a memory 600.

The memory 600 may store various pieces of information for the controller 500 to drive the substrate etching apparatus 10. For example, the memory 600 may store various information, programs, algorithms, or the like for driving the substrate etching apparatus 10, for example, the spray amount of etching solution EL, an algorithm for calculating the amount of etching solution EL, which is to be sprayed based on a height difference in the etching solution EL.

Accordingly, the controller 500 may control the rotation drive unit 100, the first nozzle unit 200, the second nozzle unit 300, and the height measuring unit 400 based on the information stored in the memory 600.

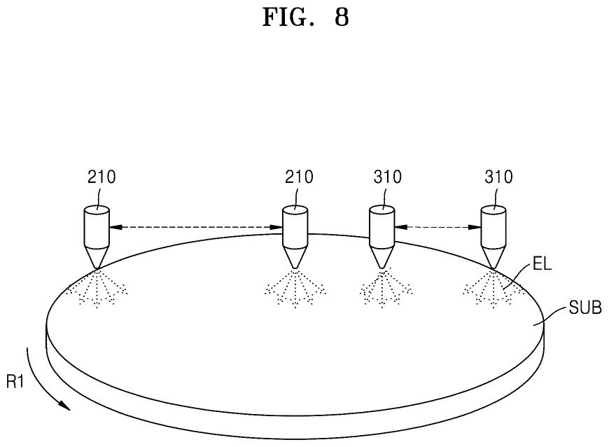

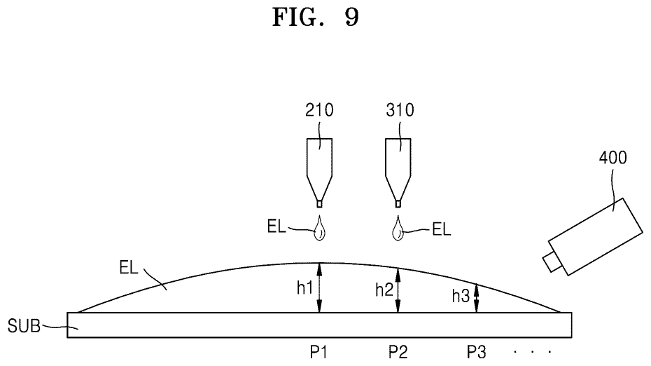

FIG. 8 is a diagram for describing the driving of the first nozzle unit 200 and the second nozzle unit 300 of FIG. 4, and FIG. 9 is a diagram for describing a driving method of the substrate etching apparatus 10 of FIG. 4.

Referring to FIGS. 8 and 9, the first nozzle unit 200 and the second nozzle unit 300 may be arranged on the substrate SUB and spray the etching solution EL onto the substrate SUB.

As an embodiment, the first nozzle unit 200 and the second nozzle unit 300 may be each independently driven.

In detail, the first nozzle unit 200 may spray a preset amount of etching solution EL onto the substrate SUB while etching of the substrate SUB is performed. As the substrate SUB is rotated by the rotation drive unit 100, the etching solution EL sprayed by the first nozzle unit 200 may be radiated by centrifugal force from a point from which the etching solution EL is dispersed. Thus, the etching solution EL is radiated in a width direction of the substrate SUB by dispersion, and thereby a height gradient is generated in the etching solution EL.

To compensate for this, the second nozzle unit 300 may spray the etching solution EL onto the substrate SUB based on the height difference in the etching solution EL which has been sprayed onto the substrate SUB. To express this from another perspective, while the first nozzle unit 200 is a component that sprays the etching solution EL onto the substrate SUB for an etching process, the second nozzle unit 300 may be expressed as a component that controls the dip level of the etching solution EL by spraying the etching solution EL in response to the dispersion of the etching solution EL sprayed by the first nozzle unit 200.

As an embodiment, the first nozzle unit 200 and the second nozzle unit 300 may spray the same etching solution EL. That is, the second nozzle unit 300 may control the dip level of the etching solution EL by spraying the same etching solution EL as sprayed by the first nozzle unit 200.

As an embodiment, while etching is being performed, the first nozzle unit 200 and the second nozzle unit 300 may spray the etching solution EL onto the substrate SUB in a spray manner. As an example, the first nozzle unit 200 and the second nozzle unit 300 may spray the etching solution EL in a fan shape onto the substrate SUB.

Accordingly, a speed at which a metal layer formed on the substrate SUB is reduced may be reduced, and the etching stop phenomenon may be reduced or prevented.

The first nozzle unit 200 and the second nozzle unit 300 may be positioned at different positions from each other with respect to the substrate SUB. In detail, the first nozzle portion 210 and the second nozzle portion 310 may be positioned at different positions with respect to the substrate SUB.

As an embodiment, the first nozzle portion 210 of the first nozzle unit 200 may be positioned closer to a center portion of the substrate SUB than the second nozzle portion 310 of the second nozzle unit 300. Here, the center portion of the substrate SUB may refer to a center portion thereof with respect to the width direction of the substrate SUB. Accordingly, the first nozzle portion 210 may spray the etching solution EL to a portion closer to the center portion of the substrate SUB than the second nozzle portion 310, and the second nozzle portion 310 may control the dip level of the etching solution EL by spraying the etching solution EL further from the center portion of the substrate SUB than the first nozzle portion 210.

As an embodiment, the first nozzle unit 200 may spray a greater amount of the etching solution EL compared to the second nozzle unit 300. As described herein, as the second nozzle unit 300 controls the dip level of the etching solution EL, the second nozzle unit 300 may compensate for the height difference in the etching solution EL by spraying less etching solution EL than the first nozzle unit 200 according to the height of the etching solution EL sprayed on the substrate SUB.

As an embodiment, the first nozzle unit 200 may spray the etching solution EL while moving in a direction away from the center portion of the substrate SUB, as illustrated in FIG. 8. For example, the first nozzle portion 210 may spray the etching solution EL while moving in a direction away from the center portion of the substrate SUB. Accordingly, the first nozzle portion 210 may spray the etching solution EL at multiple positions on the substrate SUB while moving, rather than continuously spraying the etching solution EL at only one position on the substrate SUB.

As an embodiment, the first nozzle unit 200 may spray a smaller amount of the etching solution EL the farther away from the center portion of the substrate SUB. For example, the first nozzle portion 210 may spray a smaller amount of the etching solution EL while moving away from the center portion of the substrate SUB. To explain this in detail, as the etching solution EL is radiated in the width direction of the substrate SUB by rotation of the substrate SUB, the etching solution EL may be continuously supplied to a location spaced apart from the center portion of the substrate SUB. Accordingly, the first nozzle portion 210 may control excessive supply of the etching solution EL by spraying a smaller amount of the etching solution EL while moving in a direction away from the center portion of the substrate SUB.

As an embodiment, the first nozzle unit 200 may spray the etching solution EL at a lower spray pressure the farther away from the center portion of the substrate SUB. For example, the first nozzle portion 210 may spray the etching solution EL at a lower spray pressure while moving in a direction away from the center portion of the substrate SUB. Thus, the etching solution EL may be distributed with a smaller height gradient over the entire area of the substrate SUB.

As an embodiment, the second nozzle unit 300 may spray the etching solution EL while moving in a direction away from the center portion of the substrate SUB, as illustrated in FIG. 8. For example, the second nozzle portion 310 may spray the etching solution EL while moving in a direction away from the center portion of the substrate SUB. Accordingly, the second nozzle portion 310 may spray the etching solution EL at multiple positions on the substrate SUB while moving, rather than continuously spraying the etching solution EL at only one position on the substrate SUB.

As an embodiment, the second nozzle unit 300 may spray a smaller amount of the etching solution EL the farther away from the center portion of the substrate SUB. For example, the second nozzle portion 310 may spray a smaller amount of the etching solution EL while moving in a direction away from the center portion of the substrate SUB. To explain this in detail, as the etching solution EL is radiated in the width direction of the substrate SUB by rotation of the substrate SUB, the etching solution EL may be continuously supplied to a location spaced apart from the center portion of the substrate SUB. Accordingly, the second nozzle portion 310 may control excessive supply of the etching solution EL by spraying a smaller amount of the etching solution EL while moving in a direction away from the center portion of the substrate SUB.

As an embodiment, the second nozzle unit 300 may spray the etching solution EL at a lower spray pressure the farther away from the center portion of the substrate SUB. For example, the second nozzle portion 310 may spray the etching solution EL with a lower spray pressure while moving in a direction away from the center portion of the substrate SUB. Therefore, the etching solution EL may be distributed with a smaller height gradient over the entire area of the substrate SUB.

Driving of the height measuring unit 400 will be described with reference to FIG. 9 below.

The etching solution EL sprayed onto the substrate SUB by the first nozzle portion 210 has a lower height while moving away from the center portion of the substrate SUB. For example, as illustrated in FIG. 9, heights h1, h2, h3, . . . of a plurality of positions P1, P2, P3, . . . on the substrate SUB are smaller away from the center portion of the substrate SUB. Accordingly, the second nozzle portion 310 may control the dip level of the etching solution EL by spraying the etching solution EL onto the substrate SUB at a different position compared to the first nozzle portion 210.

As an embodiment, the height measuring unit 400 may measure the height of the etching solution EL at multiple positions in a direction away from the center portion of the substrate SUB. That is, the height measuring unit 400 may measure the heights h1, h2, h3, . . . of the etching solution EL at each of the plurality of positions P1, P2, P3, . . . in the direction away from the center portion of the substrate SUB. In this case, the controller 500 may control the second nozzle unit 300 based on values of the heights h1, h2, h3, . . . of the etching solution EL, which are measured by the height measuring unit 400. For example, the second nozzle controller 320 may control the second nozzle portion 310 to spray different amounts of etching solution EL at the positions P1, P2, P3, . . . , respectively, based on the values of the heights h1, h2, h3, . . . of the etching solution EL.

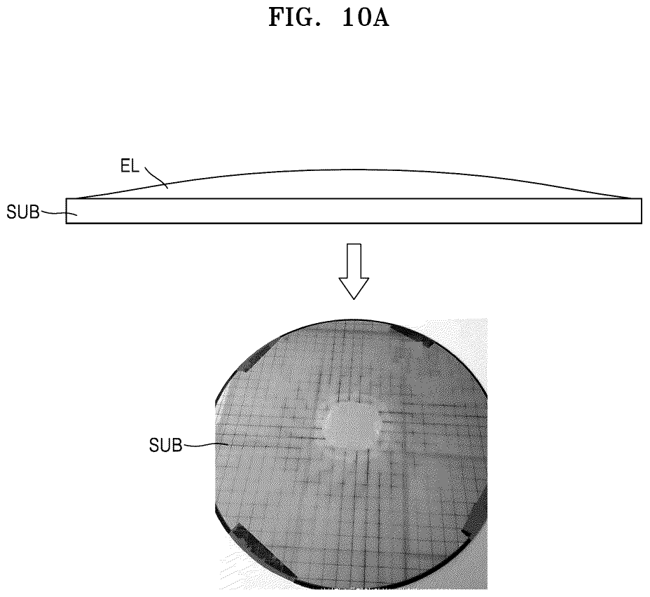

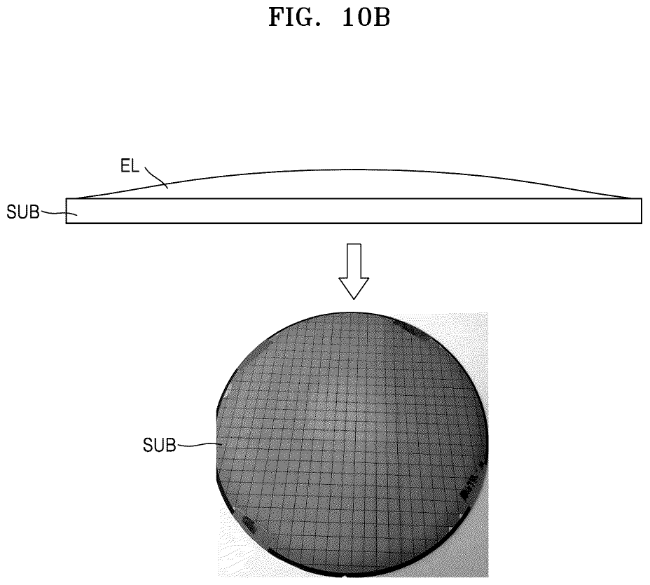

FIG. 10A is a diagram schematically illustrating the substrate SUB being etched by a substrate etching apparatus according to the related art, and FIG. 10B is a diagram schematically illustrating the substrate SUB being etched by a substrate etching apparatus according to the present disclosure.

Referring to FIG. 10A, the substrate etching apparatus according to the related art performs etching while supplying an etching solution onto a substrate without controlling the dip level of the etching solution. Thus, the etching solution did not have a uniform height distribution, and as a result, the metal layer was reduced in a certain area, causing an etching stop phenomenon where etching was stopped. In some cases, as illustrated in FIG. 10A, the substrate is not etched precisely to a target level (e.g., a required level) due to the etching stop phenomenon.

In contrast, referring to FIG. 10B, the substrate etching apparatus 10 according to the present disclosure may perform etching while supplying the etching solution EL onto the substrate SUB while controlling the dip level of the etching solution EL. Accordingly, the etching solution EL may have a relatively uniform height distribution, and as a result, the etching stop phenomenon may be reduced or prevented, and accordingly, etching of the metal layer may be performed stably and precisely. For example, as illustrated in FIG. 10B, the substrate SUB is precisely etched to a target level (e.g., a required level) due to the etching stop phenomenon.

In particular, when a metal having a relatively high reducing power such as, for example, silver (Ag) is formed to form a metal layer such as, for example, the pixel electrode 51 on the substrate SUB, there is a high probability that the etching stop phenomenon will occur because the reduction speed of the metal exceeds the etching speed. However, the substrate etching apparatus 10 according to the present disclosure may control the reduction speed of the metal by controlling the dip level of the etching solution EL, thus supporting techniques in which a metal such as, for example, silver (Ag) having a relatively high reducing power may be used to form a metal layer such as, for example, the pixel electrode 51.

Hereinafter, a substrate etching method according to another aspect of the present disclosure will be described.

For the convenience of description, details that are identical to the previously described ones or that may be easily modified and applied by a person with ordinary knowledge in the technical field to which the present disclosure pertains will be omitted or briefly described herein.

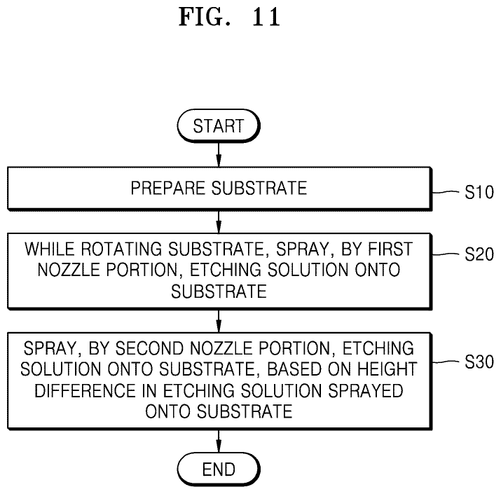

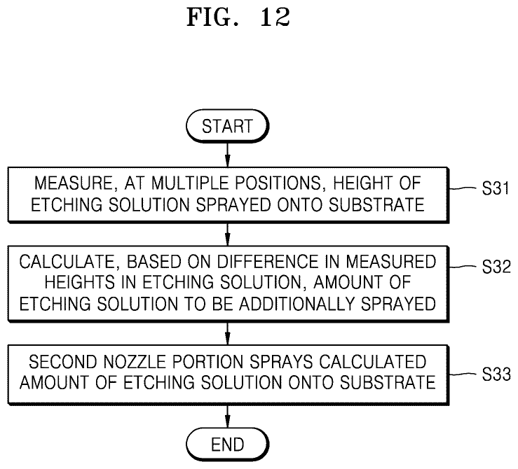

FIG. 11 is a flowchart for describing a substrate etching method according to an embodiment of the present disclosure, and FIG. 12 is a flowchart for describing an operation in which the second nozzle portion 310 of FIG. 8 sprays an etching solution onto a substrate. For example, the operations described with reference to the flowchart of FIG. 12 may be implemented at operation S30 of FIG. 11.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added.

Referring to FIGS. 11 and 12, the substrate etching method according to an embodiment of the present disclosure may include operation S10 of preparing the substrate SUB, operation S20 of spraying, by the first nozzle portion 210, the etching solution EL onto the substrate SUB, and operation S30 of spraying, by the second nozzle portion 310, the etching solution EL onto the substrate SUB.

Operation S10 of preparing the substrate SUB may be an operation of preparing the substrate SUB in which at least one layer is formed on the substrate SUB described with reference to FIGS. 1 to 3.

For example, operation S10 of preparing the substrate SUB may include an operation of stacking a material for forming a pattern of the pixel electrode 51 on the substrate SUB. As an example, operation S10 of preparing the substrate SUB may include an operation of forming a metal layer for forming the pixel electrode 51 on the substrate SUB. For example, the metal layer for forming the pixel electrode 51 may include silver (Ag).

Operation S20 in which the first nozzle portion 210 sprays the etching solution EL onto the substrate SUB may be an operation in which the first nozzle portion 210 sprays the etching solution EL onto the substrate SUB while the substrate SUB is mounted on the rotation drive unit 100 and is rotated. Specifically, the substrate SUB may be arranged on the turntable 110 of the rotation drive unit, and the rotation module 120 may rotate the substrate SUB arranged on the turntable 110 by rotating the turntable 110.

Operation S20 in which the first nozzle portion 210 sprays the etching solution EL onto the substrate SUB may be an operation in which the first nozzle portion 210 sprays a preset amount of the etching solution EL onto the substrate SUB while etching of the substrate SUB is performed. As the substrate SUB is rotated by the rotation drive unit 100, the etching solution EL sprayed by the first nozzle unit 200 may be radiated by centrifugal force from a point where the etching solution EL is dispersed. Therefore, the etching solution EL is radiated in the width direction of the substrate SUB by dispersion, and thereby a height gradient is generated in the etching solution EL.

Operation S30 in which the second nozzle portion 310 sprays the etching solution EL onto the substrate SUB may be an operation of controlling the dip level of the etching solution EL by compensating for the height gradient of the etching solution EL which has been sprayed onto the substrate SUB. That is, the second nozzle portion 310 may spray the etching solution EL onto the substrate SUB based on the height difference in the etching solution EL which has been sprayed onto the substrate SUB.

For this purpose, the first nozzle portion 210 and the second nozzle portion 310 may be each independently driven. That is, the first nozzle portion 210 may spray the etching solution EL onto the substrate SUB for an etching process, and the second nozzle portion 310 may control the dip level of the etching solution EL by independently spraying the etching solution EL relative to the first nozzle portion 210 in response to the dispersion of the etching solution EL sprayed by the first nozzle portion 210.

As an embodiment, the first nozzle portion 210 and the second nozzle portion 310 may spray the same etching solution EL. That is, the second nozzle portion 310 may control the dip level of the etching solution EL by spraying the same etching solution EL as the first nozzle portion 210.

As an embodiment, the first nozzle portion 210 and the second nozzle portion 310 may spray the etching solution EL onto the substrate SUB in a spray manner while etching is performed. As an example, the first nozzle portion 210 and the second nozzle portion 310 may spray the etching solution EL in a fan shape onto the substrate SUB.

The first nozzle portion 210 and the second nozzle portion 310 may be positioned at different positions with respect to the substrate SUB.

As an embodiment, the first nozzle portion 210 may be positioned closer to the center portion of the substrate SUB than the second nozzle portion 310. Accordingly, the first nozzle portion 210 may spray the etching solution EL closer to the center portion of the substrate SUB compared to the second nozzle portion 310, and the second nozzle portion 310 may control the dip level of the etching solution EL by spraying the etching solution EL further from the center portion of the substrate SUB compared to the first nozzle portion 210.

As an embodiment, the first nozzle portion 210 may spray a greater amount of etching solution EL than the second nozzle portion 310. As described herein, since the second nozzle portion 310 controls the dip level of the etching solution EL, the second nozzle portion 310 may compensate for the height difference in the etching solution EL by spraying less etching solution EL than the first nozzle portion 210 according to the height of the etching solution EL which has been sprayed on the substrate SUB.

As an embodiment, the first nozzle portion 210 or the second nozzle portion 310 may spray the etching solution EL while moving in a direction away from the center portion of the substrate SUB. Accordingly, the first nozzle portion 210 or the second nozzle portion 310 may spray the etching solution EL at multiple positions on the substrate SUB while moving, rather than continuously spraying the etching solution EL at only one position on the substrate SUB.

As an embodiment, the first nozzle portion 210 or the second nozzle portion 310 may spray a smaller amount of the etching solution EL the farther away from the center portion of the substrate SUB. For example, the first nozzle portion 210 or the second nozzle portion 310 may spray a smaller amount of the etching solution EL while moving in a direction away from the center portion of the substrate SUB.

As an embodiment, the first nozzle portion 210 or the second nozzle portion 310 may spray the etching solution EL at a lower spray pressure the farther away from the center portion of the substrate SUB. Therefore, the etching solution EL may be distributed with a smaller height gradient over the entire area of the substrate SUB.

As an embodiment, operation S30 of spraying the etching solution EL onto the substrate SUB by the second nozzle portion 310 may include operation S31 of measuring, at multiple positions, the height of the etching solution EL which has been sprayed onto the substrate SUB and operation S32 of calculating, based on a difference between the measured heights of the etching solution EL, an amount of the etching solution EL to be additionally sprayed.

Operation S31 of measuring, at multiple positions, the height of the etching solution EL sprayed on the substrate SUB may be performed by the height measuring unit 400.

As described herein, the etching solution EL which has been sprayed onto the substrate SUB by the first nozzle portion 210 has a lower height away from the center portion of the substrate SUB. Accordingly, the second nozzle portion 310 may control the dip level of the etching solution EL by spraying the etching solution EL onto the substrate SUB at a different position compared to the first nozzle portion 210.

As an embodiment, the height of the etching solution EL sprayed on the substrate SUB may be measured at multiple positions in a direction away from the center portion of the substrate SUB by the height measuring unit 400. The controller 500 may calculate the amount of etching solution EL to be additionally sprayed by the second nozzle portion 310, based on values of heights of the etching solution EL, which are measured by the height measuring unit 400.

In an embodiment, operation S30 in which the second nozzle portion 310 sprays the etching solution EL onto the substrate SUB may further include operation S33 in which the second nozzle portion 310 sprays the calculated amount of the etching solution EL onto the substrate SUB. That is, the controller 500 may control the second nozzle portion 310 such that the second nozzle portion 310 may spray the etching solution EL in an amount equivalent to the calculated additional spray amount of the etching solution EL. Accordingly, the second nozzle portion 310 may control the dip level of the etching solution EL by spraying an appropriate amount of the etching solution EL such that a concentration gradient of the etching solution EL sprayed on the substrate SUB is minimized.

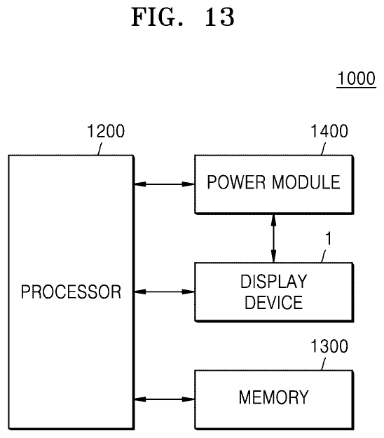

FIG. 13 is a block diagram of an electronic device according to an embodiment of the present disclosure.

Referring to FIG. 13, an electronic device 1000 according to an embodiment may include the display device 1, a processor 1200, a memory 1300, and a power module 1400.

The display device 1 may include the display device 1 manufactured by the substrate etching apparatus 10 or the substrate etching method described herein.

The display device 1 may receive data from the processor 1200 and provide visual information. The display device 1 may include the display device 1 according to the embodiments of the present disclosure described herein.

The processor 1200 may include at least one of a central processing unit (CPU), an application processor (AP), a graphics processing unit (GPU), a communication processor (CP), an image signal processor (ISP), and a controller. For example, the processor 1200 may operate by executing at least one program.

The memory 1300 may store data information supportive of the operation of the processor 1200 or the display device 1. For example, the memory 1300 may store the at least one program. In an example in which the processor 1200 executes an application stored in the memory 1300, an image data signal and/or an input control signal is transmitted to the display device 1, and the display device 1 may process the received signal and output image information through a display screen.

The power module 1400 may include a power supply module, such as, for example, a power adapter or a battery device, and a power conversion module that converts power supplied by the power supply module to generate power for the operation of the electronic device 1000. For example, the power module 1400 may supply power to the display device 1.

At least one of the components of the electronic device 1000 described herein may be included in the display device 1 according to the embodiments described herein. In some embodiments, some of individual modules functionally included within one module may be included within the display device 1 and others may be provided separately from the display device 1.

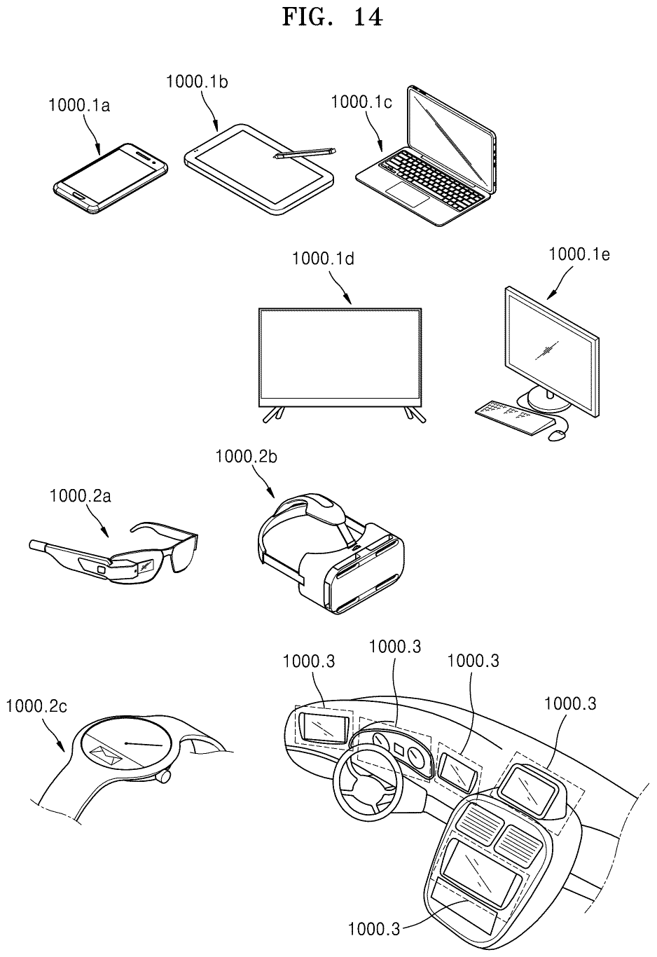

FIG. 14 is a schematic diagram of an electronic device according to various embodiments.

Referring to FIG. 14, various electronic devices to which a display device according to the embodiments of the present disclosure is applied may include not only image-displaying electronic devices such as, for example, a smart phone 1000.1a, a tablet personal computer (PC) 1000.1b, a laptop computer 1000.1c, a television (TV) 1000.1d, and a desk monitor 1000.1e, but also wearable electronic devices including a display device, such as, for example, smart glasses 1000.2a, a head mounted display 1000.2b, and a smart watch 1000.2c, and a vehicle electronic device 1000.3 including a display device, such as, for example, an instrument panel, a center fascia, a center information display (CID) arranged on a dashboard, and a room mirror display of an automobile.

As described herein, according to the substrate etching apparatus and the substrate etching method according to the embodiments of the present disclosure, the substrate etching apparatus and the substrate etching method with improved optical characteristics and improved precision may be provided.

Specifically, according to the substrate etching apparatus and the substrate etching method according to the present disclosure, the height of the etching solution is measured, and the etching solution is sprayed through different nozzle units based on the measured height of the etching solution, thereby controlling the dip level of the etching solution. Accordingly, as the height difference in the etching solution is minimized by controlling the dip level of the etching solution, the etching stop phenomenon in which etching is stopped due to reduction of a metal layer for forming an electrode may be reduced or prevented. Furthermore, according to the substrate etching apparatus and the substrate etching method according to the present disclosure, due to the reduction or prevention of the etching stop phenomenon, a metal having a relatively strong reducing power may be used as a pixel electrode.

In some embodiments, according to the substrate etching apparatus and the substrate etching method according to the present disclosure, as a metal with a strong reducing power, such as, for example, silver (Ag), may be used as a pixel electrode, a display device manufactured thereby may have improved optical characteristics, such as, for example, reflectance.

While each of the embodiments described herein may be implemented independently, it is obvious that the structure of each embodiment may be applied in combination with other embodiments.

Although the present disclosure has been described with reference to the embodiments illustrated in the drawings, these are examples, and those skilled in the art will understand that various modifications and equivalent other embodiments may be made therefrom. Therefore, the technical protection scope of the present disclosure should be determined by the technical idea of the appended patent claims.

The specific implementations described in the embodiments are intended to be illustrative only and do not limit the scope of the examples in any way. Moreover, no item or component is essential to the practice of the present disclosure unless the element is specifically described as “essential” or “critical”.

The use of the terms “a” and “an” and “the” and similar referents in the context of describing the present disclosure (especially in the context of the following claims) are to be construed to cover both the singular and the plural. Furthermore, recitation of ranges of values herein are intended to serve as a shorthand method of referring individually to each separate value falling within the range, unless otherwise indicated herein, and each separate value is incorporated into the specification as if it were individually recited herein. Finally, the steps of all methods described herein can be performed in any suitable order unless otherwise indicated herein or otherwise clearly contradicted by context. The present disclosure is not necessarily limited to the order in which the above steps are described. The use of any and all examples, or example language provided herein, is intended to better illuminate the present disclosure and does not pose a limitation on the scope of the present disclosure unless otherwise claimed. Numerous modifications and adaptations will be readily apparent to those skilled in this art without departing from the spirit and scope of the present disclosure.

Embodiments of the present disclosure may provide a substrate etching apparatus and a substrate etching method for manufacturing a display substrate with improved optical properties.

However, these effects are examples and the effects of the present disclosure are not limited thereto.

What is claimed is:

1. A substrate etching apparatus comprising:
a rotation drive unit comprising:
a turntable on which a substrate is arranged; and
a rotation module that rotates the turntable;
a first nozzle unit which sprays an etching solution onto the substrate;
a second nozzle unit positioned at a different position with respect to the substrate compared to the first nozzle unit and which sprays the etching solution onto the substrate based on a height difference in the etching solution which has been sprayed onto the substrate; and
a controller which controls a spray amount of the etching solution by at least one of the first nozzle unit and the second nozzle unit.

2. The substrate etching apparatus of claim 1, wherein the first nozzle unit and the second nozzle unit are each independently driven.

3. The substrate etching apparatus of claim 1, wherein the etching solution sprayed by the first nozzle unit is radially discharged by centrifugal force.

4. The substrate etching apparatus of claim 1, wherein the first nozzle unit and the second nozzle unit spray the etching solution in a spray manner while etching is performed on the substrate.

5. The substrate etching apparatus of claim 1, wherein the first nozzle unit is positioned closer to a center portion of the substrate than the second nozzle unit.

6. The substrate etching apparatus of claim 1, wherein the first nozzle unit sprays a greater amount of the etching solution compared to the second nozzle unit.

7. The substrate etching apparatus of claim 1, wherein the second nozzle unit sprays the etching solution while moving in a direction away from a center portion of the substrate.

8. The substrate etching apparatus of claim 7, wherein the second nozzle unit sprays a smaller amount of the etching solution the farther away from the center portion of the substrate.

9. The substrate etching apparatus of claim 7, wherein the second nozzle unit sprays the etching solution at a lower spray pressure the farther away from the center portion of the substrate.

10. The substrate etching apparatus of claim 1, further comprising a height measuring unit measuring a height of the etching solution which has been sprayed onto and is distributed on the substrate.

11. The substrate etching apparatus of claim 10, wherein:
the height measuring unit measures the height of the etching solution at multiple positions in a direction away from a center portion of the substrate, and
the height difference is based on a difference between the measured heights.

12. A substrate etching method comprising:
preparing a substrate;
while rotating the substrate, spraying, by a first nozzle portion, an etching solution onto the substrate; and
spraying, by a second nozzle portion, the etching solution onto the substrate based on a height difference in the etching solution which has been sprayed onto the substrate.

13. The substrate etching method of claim 12, wherein the first nozzle portion and the second nozzle portion are each independently driven and spray the etching solution onto the substrate.

14. The substrate etching method of claim 12, wherein the etching solution sprayed by the first nozzle unit is radially discharged by centrifugal force.

15. The substrate etching method of claim 12, wherein the first nozzle portion sprays a greater amount of the etching solution compared to the second nozzle portion.

16. The substrate etching method of claim 12, wherein the second nozzle portion sprays the etching solution while moving in a direction away from a center portion of the substrate.

17. The substrate etching method of claim 16, wherein the second nozzle portion sprays a smaller amount of the etching solution the farther away from the center portion of the substrate.

18. The substrate etching method of claim 12, wherein the spraying, by the second nozzle portion, of the etching solution onto the substrate comprises:
measuring, at multiple positions, a height of the etching solution which has been sprayed onto the substrate; and
calculating, based on a difference between the measured heights of the etching solution, an amount of etching solution to be additionally sprayed.

19. The substrate etching method of claim 18, wherein the spraying, by the second nozzle portion, of the etching solution onto the substrate further comprises spraying, by the second nozzle portion, the etching solution onto the substrate based on the calculated amount.

20. The substrate etching method of claim 18, wherein the measuring, at the multiple positions, the height of the etching solution which has been sprayed on the substrate comprises measuring the height of the etching solution at the multiple positions in a direction away from a center portion of the substrate.
